(19) United States
(12) Patent Application Publication
(10) Pub. No.: US 2024/0360555 A1
(43) Pub. Date: Oct. 31, 2024

(54) PRECURSOR CONTAINER APPARATUS

(71) Applicant: Picosun Oy, Espoo (FI)

(72) Inventor: Marko PUDAS, Espoo (FI)

(21) Appl. No.: 18/682,450

(22) PCT Filed: Sep. 5, 2022
(86) PCT No.: PCT/FI2022/050584

§ 371 Date: Feb. 9, 2024

(30) Foreign Application Priority Data
Sep. 7, 2021 (FI) 20215939

(51) Int. Cl. C23C 16/448

(52) U.S. Cl. CPC C23C 16/4482

(57) ABSTRACT

A precursor container apparatus, comprising a first volume to house precursor material, a second volume separated from the first volume by a partition wall eliminating gas exchange between the first and second volumes. The precursor container apparatus further comprises a route for the precursor material from the first volume to the second volume and an arrangement configured to raise a surface level of the precursor material via the route into the second volume and to maintain the surface level at a pre-determined level within the second volume.

### FIELD OF THE INVENTION

The present invention generally relates to precursor container apparatus.

### BACKGROUND OF THE INVENTION

This section illustrates useful background information without admission of any technique described herein representative of the state of the art.

In CVD (Chemical Vapor Deposition) and ALD (Atomic Layer Deposition) processes a certain minimum amount of reactive gas, precursor, is needed to fill a substrate surface with at least one atomic layer. For ideal ALD processes carried out in optimum temperatures, an excess amount of the precursor does not cause negative effects on a growth rate of a deposited thin film. However, depending on materials to be deposited and the prevailing or requested deposition conditions, an excess amount of precursor chemical may have an effect on the film growth rate. Further some chemicals may be significantly expensive, and using excessive quantities may simply produce unnecessary waste. For CVD, the quantity of precursor may be even more relevant, or for processes which are combinations of ALD and CVD, for example ALD processed without a purge step. When a chemical level changes in a precursor bottle, which will result in an increasing or decreasing volume for the chemical to evaporate in, the dosage per gas pulse will change and thus affect the film growth. Yet further, the addition of inert gas (carrier gas, such as N₂ or Ar) can be significant enough to alter pressure, concentration and/or flow speed of the fluids to the extent that will affect the deposition quality. On the other hand, release of the pressure build-up on the precursor container can cause unwanted variation in pressures and gas flow to the reactor and even over the substrates during deposition. Thus, there is a need for mitigating issues caused by the varying gas volume inside the precursor container, and additionally a need for providing an improvement for gas feed arrangements of ALD/CVD reactors.

### SUMMARY

It is an object of certain embodiments of the invention to provide an improved precursor container apparatus or at least to provide an alternative solution to existing technology.

According to a first example aspect of the invention there is provided a precursor container apparatus, comprising:
a first volume to house precursor material;
a second volume separated from the first volume by a partition wall preventing gas exchange between the first and second volumes, the precursor container apparatus further comprising:
a route for the precursor material from the first volume to the second volume; and
an arrangement configured to raise a surface level of the precursor material via the route into the second volume and to maintain the surface level of the precursor material at a pre-determined level within the second volume.

In certain embodiments, a valve is arranged to facilitate the route of the precursor material from the first volume to the second volume. The valve may be any suitable valve, such as a two-way-valve. In certain embodiments, the valve is a manual valve, such as a manual two-way-valve. The route can be closed by the valve, for example, for transportation and installation.

In certain embodiments, the route is constructed from the partition wall. In certain embodiments, the route is a conduit, pipe or a tube extending from the first volume to the second volume.

In certain embodiments, an inlet is arranged or attached to the precursor container apparatus for providing carrier gas to the first volume. In certain embodiments, an inlet is arranged or attached to the first volume for providing carrier gas to the first volume for raising the precursor material level via the route to the second volume following an increase in pressure in the first volume. In certain embodiments, an inlet is arranged or attached to the first volume for providing carrier gas to the first volume above the precursor material surface level. In certain embodiments, an inlet is arranged or attached to the first volume for providing carrier gas to the first volume below the precursor material surface level or within the precursor material.

The carrier gas provided to the first volume raises the pressure in the first volume. The increased pressure pushes the precursor material from the first volume via the route to the second volume. By monitoring and controlling the pressure of the carrier gas, the surface level of the precursor material within the second volume can be maintained at a pre-determined level.

In certain embodiments, the precursor material is liquid precursor material.

In certain embodiments, an increase in pressure in the first volume causes precursor material to move from the first volume to the second volume, with the exact amount of precursor material moving from the first volume to the second volume being determined by controlling the pressure. If the amount of gas is constant in the second volume, an exact pre-determined volume of precursor material can be in gas phase in the second volume, therefore the quantity of the precursor material provided to a reaction chamber can be controlled and, in particular, kept constant per pulse.

In certain embodiments, the arrangement configured to raise a surface level controls the pressure in the second volume such that the pressure is lower than pressure in the first volume thereby raising the precursor material to the second volume via the route.

In certain embodiments, the arrangement configured to raise a surface level of the precursor material comprises an inlet arranged or attached to the first volume for providing carrier gas to the first volume, and optionally a valve arranged or attached to the inlet, a mass flow controller and/or a pressure monitor.

In certain embodiments, the arrangement further comprises means for indicating the level of the precursor material in the second volume and/or a pressure sensor for monitoring pressure in the second volume.

In certain embodiments, an inlet is arranged or attached to the second volume for providing carrier gas to the second volume.

In certain embodiments, an outlet is arranged or attached to the second volume for discharging precursor material from the second volume. In certain embodiments, an outlet comprising a valve is arranged or attached to the second volume.

In certain embodiments, the precursor container apparatus further comprises a buffer chamber. In certain embodiments, the precursor container apparatus is configured to guide precursor material from the second volume to the buffer chamber. In certain embodiments, the precursor container apparatus is configured to guide precursor material from the second volume to the reaction chamber by bypassing the buffer chamber.

In certain embodiments, the buffer chamber has a buffer volume. In certain embodiments, the precursor material is guided from the second volume to the buffer volume. The buffer volume enables the quantity of the precursor material, provided to a reaction chamber, to be kept constant per pulse.

In certain embodiments, a cross section of the buffer chamber is wider between inlet and outlet sections. This configuration allows the chamber to be pushed empty without a tail. The buffer chamber expands when precursor material and/or carrier gas flow to the buffer chamber. During a pulse, the buffer chamber squeezes thereby pushing precursor material and/or carrier gas from the buffer chamber to the reaction chamber without a tail. The buffer chamber has a constant crossflow, preferably without turbulence (plug-flow).

In certain embodiments, the precursor material is guided from the second volume directly to the reaction chamber by bypassing the buffer chamber having the buffer volume.

In certain embodiments, the precursor material is guided to the reaction chamber from both the buffer volume and directly from the second volume by a bypassing route.

In certain embodiments, the first volume, the second volume, the buffer volume, the precursor material, the valves and/or inlets and outlets are heated by heating means independently or separately. In certain embodiments, the buffer volume is heated more than the precursor material. In certain embodiments, the heating means are arranged into or attached to the first volume, the second volume and/or the buffer volume. In certain embodiments, the heating means are arranged or attached to walls of the precursor container apparatus. In certain embodiments, the heating means are arranged outside of the precursor container apparatus. In certain embodiments, the heating is implemented by conduction and/or radiation.

In certain embodiments, the first volume, the second volume, the buffer volume, the precursor material, the valves and/or inlets and outlets are cooled by cooling means independently or separately. In certain embodiments, the buffer volume is cooled more than the precursor material. In certain embodiments, the cooling means are arranged into or attached to the first volume, the second volume and/or the buffer volume. In certain embodiments, the cooling means are arranged or attached to walls of the precursor container apparatus. In certain embodiments, the cooling means are arranged outside of the precursor container apparatus. In certain embodiments, the cooling is implemented by conduction.

In certain embodiments, the precursor container apparatus is used in an atomic layer deposition, ALD, apparatus. In this context, the term ALD comprises ALD sub-types, such as MLD (Molecular Layer Deposition), plasma-assisted ALD, for example PEALD (Plasma Enhanced Atomic Layer Deposition), and photo-enhanced Atomic Layer Deposition (known also as flash enhanced ALD). In alternative embodiments, the precursor container apparatus is used in a chemical vapor deposition, CVD, apparatus.

According to a second example of the invention there is provided a method for handling precursor material in a precursor container apparatus comprising a first volume and a second volume separated by a partition wall, wherein the partition wall prevents gas exchange between the first and second volumes, the method comprising:
raising a surface level of the precursor material in the second volume via a route arranged from the first volume to the second volume; and
maintaining the surface level of the precursor material at a pre-determined level within the second volume.

In certain embodiments, the said route is provided via the partition wall, for example via an opening arranged in the partition wall. In certain embodiments, the partition wall is gas impermeable.

In certain embodiments, the surface level of liquid precursor material is maintained at a pre-determined level so as to keep an amount of precursor material constant for (subsequent) precursor material pulses.

In certain embodiments, the method comprises providing carrier gas to the first volume via an inlet.

In certain embodiments, the method comprises providing carrier gas to the first volume via an inlet for raising the precursor material level via the route to the second volume following an increase in pressure in the first volume.

In certain embodiments, the method comprises controlling the pressure in the second volume so that the pressure in the second volume is lower than the pressure in the first volume thereby raising the precursor material to the second volume via the route.

In certain embodiments, the method comprises providing carrier gas to the first volume via an inlet positioned above a precursor material surface level within the first volume.

In certain embodiments, the method comprises providing the route with a valve.

In certain embodiments, the method comprises discharging precursor material from the second volume via an outlet towards a reaction chamber.

In certain embodiments, the method comprises guiding precursor material from the second volume to a buffer chamber upstream of a reaction chamber.

Different non-binding example aspects and embodiments of the present invention have been illustrated in the foregoing. The above embodiments are used merely to explain selected aspects or steps that may be utilized in implementations of the present invention. Some embodiments may be presented only with reference to certain example aspects of the invention. It should be appreciated that corresponding embodiments apply to other example aspects as well. Any appropriate combinations of the embodiments may be formed.

### BRIEF DESCRIPTION OF THE DRAWINGS

The invention will now be described, by way of example only, with reference to the accompanying drawings, in which:

FIG. 1 shows a schematic side view of a precursor container apparatus in accordance with certain example embodiments;

FIG. 2 shows a schematic side view of a precursor container apparatus in accordance with certain further example embodiments;

FIG. 3 shows a deposition reactor in accordance with certain example embodiments; and

FIG. 4 shows a block diagram of a control system in accordance with certain example embodiments.

### DETAILED DESCRIPTION

In the following description, Atomic Layer Deposition (ALD) technology and Atomic Layer Etching (ALE) technology are used as an example.

The basics of an ALD growth mechanism are known to a skilled person. ALD is a special chemical deposition method based on sequential introduction of at least two reactive precursor species to at least one substrate. A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be either simpler or more complex. For example, the cycles can include three or more reactant vapor pulses separated by purging steps, or certain purge steps can be omitted. Or, as for plasma-assisted ALD, for example PEALD (plasma-enhanced atomic layer deposition), or for photon-assisted ALD, one or more of the deposition steps can be assisted by providing required additional energy for surface reactions through plasma or photon in-feed, respectively. Or one of the reactive precursors can be substituted by energy, leading to single precursor ALD processes. Accordingly, the pulse and purge sequence may be different depending on each particular case. The deposition cycles form a timed deposition sequence that is controlled by a logic unit or a microprocessor. Thin films grown by ALD are dense, pinhole free and have uniform thickness.

As for substrate processing steps, the at least one substrate is typically exposed to temporally separated precursor pulses in a reaction vessel (or chamber) to deposit material on the substrate surfaces by sequential self-saturating surface reactions. In the context of this application, the term ALD comprises all applicable ALD based techniques and any equivalent or closely related technologies, such as, for example the following ALD sub-types: MLD (Molecular Layer Deposition), plasma-assisted ALD, for example PEALD (Plasma Enhanced Atomic Layer Deposition) and photon-assisted or photon-enhanced Atomic Layer Deposition (known also as flash enhanced ALD or photo-ALD).

However, the invention is not limited to ALD technology, but it can be exploited in a wide variety of substrate processing apparatuses, for example, in Chemical Vapor Deposition (CVD) reactors, or in etching reactors, such as in Atomic Layer Etching (ALE) reactors.

The basics of an ALE etching mechanism are known to a skilled person. ALE is a technique in which material layers are removed from a surface using sequential reaction steps that are self-limiting. A typical ALE etching cycle comprises a modification step to form a reactive layer, and a removal step to take off only the reactive layer. The removal step may comprise using a plasma species, ions in particular, for the layer removal.

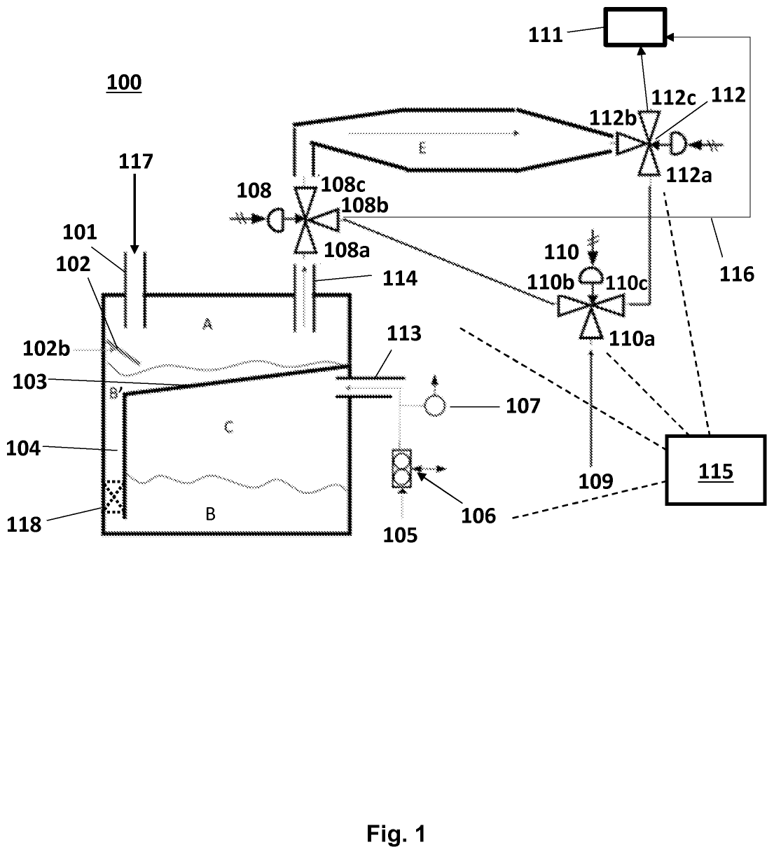

FIG. 1 shows a schematic side view of a precursor container apparatus according to an example embodiment. The precursor container apparatus 100 comprises a first volume C comprising precursor material B, preferably liquid precursor material, a second volume A separated from the first volume C by a partition wall 103 preventing gas exchange between the first volume C and the second volume A. The precursor container apparatus 100 further comprises a route 104 for the precursor material B to move from the first volume C to the second volume A and an arrangement configured to enable a surface level of the precursor material B, via the route 104, to be raised into the second volume A. The arrangement enables the surface level of the precursor material B′ to be maintained at a predetermined level within the second volume A.

In one embodiment the arrangement comprises an inlet 113 for providing carrier gas 105 to the first volume C, optionally a mass flow controller (MFC) 106 and optionally a pressure controller/sensor 107. The carrier gas 105 provided to the first volume C increases pressure in the first volume C thereby raising the precursor material B to B′ via the route 104 in the second volume A.

In one embodiment the inlet 113 is arranged to provide the carrier gas above the surface level of the precursor material B in the first volume C.

In an alternative embodiment the inlet 113 is arranged to provide the carrier gas below the surface level of the precursor material B in the first volume C.

In one embodiment the inlet 113 is arranged to the first volume C for providing carrier gas to the first volume C for raising the precursor material level to the second volume A, via the route 104 following increased pressure in the first volume C.

In one embodiment pressure in the second volume A is lowered below pressure in the first volume C thus enabling precursor material B to rise to second volume A via route 104.

In one embodiment the precursor container apparatus 100 comprises an inlet 101 for providing carrier gas 117 to the second volume A. The carrier gas line may have a mass flow controller or a pressure controller (not shown) (which may be synchronized with other pressures in the apparatus 100).

In one embodiment the inlet 113 and/or 101 comprises a valve.

In one embodiment inlet 101 or 113 or both 101 and 113 may be used for filling the precursor container apparatus with precursor material B. In one embodiment there is an additional filling port inlet (not shown), other than 101 or 113, which enables filling of precursor material (or liquid) B.

In one embodiment the precursor container apparatus 100 comprises means (or a structure) 102 to block droplets from spilling out from the route 104. The means 102 adapted to block droplets, may also comprise a sensor 102b, to indicate the level of the precursor material B, and/or a pressure sensor in the second volume, or the sensor 102b may be located under the means 102. When the level of liquid B rises to the edge of the means 102, second volume A is no longer in gaseous contact with sensor 102b, but blocked by fluid B′, thus enabling an indication of the fluid level with measurement means such as a pressure sensor or an electromagnetic sensor adapted to measure the distance to or closure of the means 102 by liquid.

In one embodiment an optional valve, such as a manual valve 118, is arranged to the route 104. The route 104 can be closed by the valve, for example, for transportation and/or installation.

In one embodiment the partition wall 103 is gas and liquid impermeable.

In one embodiment the precursor container apparatus comprises an outlet 114 for discharging precursor material and carrier gas from the second volume A.

In one embodiment the outlet 114 comprises a valve 108 which is at least a 2-way-valve (having ports 108a and 108c), or a 3-way valve (having ports 108a, 108b, and 108c). In one embodiment the valve 108 is used for providing chemicals, directly to reactor 111 as a pulse (through ports 108a and 108b). In one embodiment the precursor material and carrier gas, are first guided to a buffer chamber having a buffer volume E before a pulse. The buffer volume E enables the quantity of the precursor material provided to reactor 111 (deposition reactor) via valve 112 to be even more accurately controlled and hence kept constant per pulse.

In one embodiment the cross section of the buffer chamber E is wider between inlet and outlet sections. This configuration allows the chamber to be pushed empty without a tail. The buffer chamber expands when precursor material and/or carrier gas flow to the buffer chamber. During a pulse, the buffer chamber squeezes thereby pushing precursor material and/or carrier gas from the buffer chamber to the reaction chamber without a tail. The buffer chamber has a constant crossflow, preferably without turbulence (plug-flow).

In one embodiment chemicals, for example the precursor material and carrier gas are guided from the valve 108 through port 108b directly to the reactor 111 via line 116 by omitting the buffer volume E and valves 110, and 112.

In one embodiment the precursor material and the carrier gas are guided from the valve 108a (through port 108b) to reactor 111 via another valve 110 to which also additional carrier gas 109 can be provided. In one embodiment the precursor material and carrier gas are provided from the valve 110 via the valve 112 to the reactor 111. In one embodiment the valve 112 is a three-way-valve or a four-way-valve. An example of an applicable four-way-valve has been described in the publication WO 2018/202935 A1.

In one embodiment the carrier gas is guided from the valve 110 to the valve 108, to carry precursor and to purge the line downstream of valve 108, while the port 108a of the valve 108 may be closed.

In one embodiment the valve 110 is used to direct carrier gas 109 to the valve 108 and to the valve 112.

In one embodiment, the operation of the valve sequences comprises: all ports of the valve are open and the inlet 101 provides a flow of carrier gas to the buffer volume E having lower pressure than the second volume A. Alternatively the flow may be assisted by a pump (not shown). In a certain configuration that includes the buffer volume E, during the precursor pulsing, before or in between the pulses, a port 110c of the valve 110 guides carrier gas via the valve 112 to the reactor 111, without being in contact with the precursor or buffer volume E. Upon a pulse to the reactor 111, the following valve operation(s) follow each other with short defined intervals or the valve operation(s) take place at the same time:
1) the port 108a of the valve 108 closes, and the gas flow via the route 101 is closed or altered;
2) the valve 112 opens the buffer volume E line at least in the direction to the reactor 111 (the ports 112b and 112c are opened);
3) ports 110a and 110b of the valve 110 open to let the carrier gas 109 to the valve 108;
4) the ports 108b and 108c of the valve 108 open to let the carrier gas flow from 109 to the buffer volume and to the reactor 111;
5) the valve 112 may close the route to the valve 110, so that all gasses are flowing via the buffer volume E only;
6) the valve 108 may be partially or completely closed, to decrease the pressure on the buffer volume by the evacuation from the reactor 111;
7) the port 112b of the valve 112 to buffer volume E closes, and thus the flow of the precursor from the volume A to the buffer volume E continue via the ports 108a and 108c of the valve 108, and the flow of carrier gas 109 via the ports 110a and 110c of the valve 110 and via the ports 112a and 112c of the valve 112 to the reactor 111 resume.

In one embodiment the valve 110 is a T-connection valve. Said valve may control the flow from the port 110b to the port 108b or adjust the flow from the valve 110 to the valve 112.

In one embodiment the precursor container apparatus is operated by a control system 115. The control system comprises at least one processing unit or processor that for example transmits and/or receives signals to and/from valve controllers and sensors, mass flow controllers, and/or heater controllers.

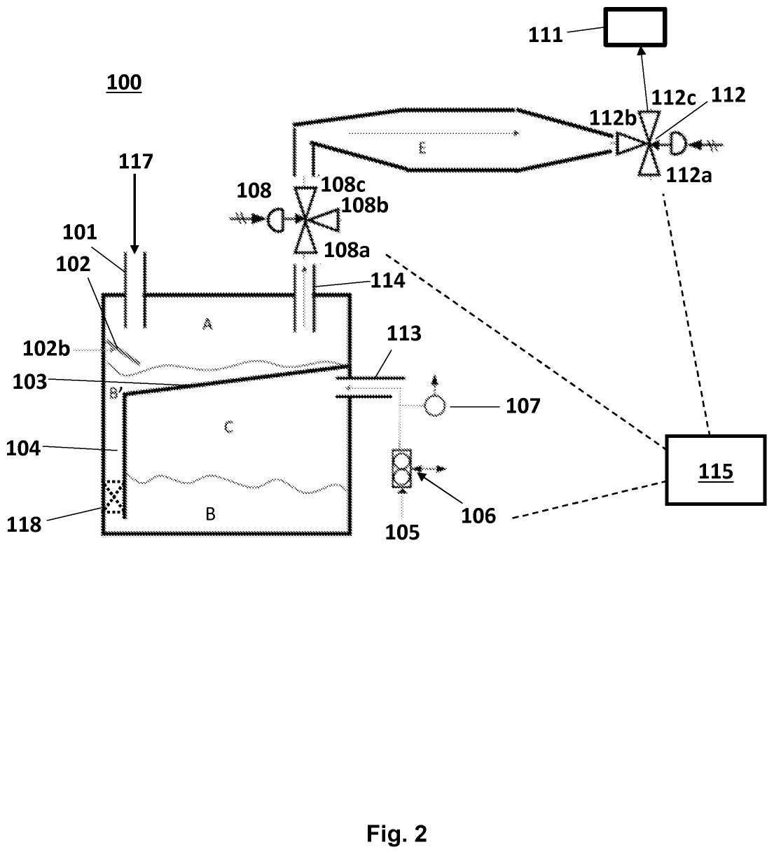

FIG. 2 shows a schematic side view of an embodiment of the precursor container apparatus according a further example embodiment in line with the embodiment shown in FIG. 1. The precursor container apparatus 100 comprises a first volume C comprising precursor material B, preferably liquid precursor material, a second volume A separated from the first volume C by a partition wall 103 preventing gas exchange between the first volume C and the second volume A. The precursor container apparatus 100 further comprises a route 104 for the precursor material B to move from the first volume C to the second volume A and an arrangement configured to enable a surface level of the precursor material B, via the route 104, to be raised into the second volume A. The arrangement enables the surface level of the precursor material B′ to be maintained at a predetermined level within the second volume A.

In one embodiment the arrangement comprises an inlet 113 for providing carrier gas 105 to the first volume C, optionally a mass flow controller (MFC) 106 and optionally a pressure controller/sensor 107. The carrier gas 105 provided to the first volume C increases pressure in the first volume C thereby raising the precursor material B to B′ via the route 104 in the second volume A.

In one embodiment the inlet 113 is arranged to provide the carrier gas above the surface level of the precursor material B in the first volume C.

In an alternative embodiment the inlet 113 is arranged to provide the carrier gas below the surface level of the precursor material B in the first volume C.

In one embodiment the inlet 113 is arranged to the first volume C for providing carrier gas to the first volume C for raising the precursor material level to the second volume A, via the route 104 following increased pressure in the first volume C.

In one embodiment pressure in the second volume A is lowered below pressure in the first volume C thus enabling precursor material B to rise to second volume A via route 104.

In one embodiment the precursor container apparatus 100 comprises an inlet 101 for providing carrier gas 117 to the second volume A. The carrier gas line may have a mass flow controller or a pressure controller (not shown), which may be synchronized with other pressures in the apparatus 100.

In one embodiment the inlet 113 and/or 101 comprises a valve.

In one embodiment the inlet 101 or 113 or both 101 and 113 may be used for filling the precursor container apparatus with precursor material B. In one embodiment there is an additional filling port inlet (not shown), other than 101 or 113, which enables filling of the precursor material B.

In one embodiment the precursor container apparatus 100 comprises means (or a structure) 102 to block droplets from spilling out from the route 104. The means 102 adapted to block droplets, may also comprise a sensor 102b, to indicate the level of the precursor material B, and/or a pressure sensor in the second volume, or the sensor 102b may be located under the means 102. When the level of liquid B rises to the edge of 102, the second volume A is no longer in gaseous contact with sensor 102b, but blocked by fluid B′, thus enabling an indication of the fluid level with measurement means such as a pressure sensor or an electromagnetic sensor adapted to measure the distance to or closure of the means 102 by liquid.

In one embodiment an optional valve, such as a manual valve 118, is arranged to the route 104. The route 104 can be closed by the valve, for example, for transportation and/or installation.

In one embodiment the partition wall 103 is gas and liquid impermeable.

In one embodiment the precursor container apparatus comprises an outlet 114 for discharging precursor material and carrier gas from the second volume A.

In one embodiment the outlet 114 comprises a valve 108 which is at least a 2-way-valve (having ports 108a and 108c), or a 3-way valve (having ports 108a, 108b, and 108c). In one embodiment the precursor material and carrier gas, are first guided to a buffer chamber having a buffer volume E before a pulse. The buffer volume E enables the quantity of the precursor material provided to reactor 111 (deposition reactor) via the valve 112 to be even more accurately controlled and hence kept constant per pulse.

In one embodiment the valve 112 is a three-way-valve or a four-way-valve.

In one embodiment the cross section of the buffer chamber E is wider between inlet and outlet sections. This configuration allows the chamber to be pushed empty without a tail. The buffer chamber expands when precursor material and/or carrier gas flow to the buffer chamber. During a pulse, the buffer chamber squeezes thereby pushing precursor material and/or carrier gas from the buffer chamber to the reaction chamber without a tail. The buffer chamber has a constant crossflow, preferably without turbulence (plug-flow).

In one embodiment the precursor container apparatus is operated by a control system 115. The control system comprises at least one processing unit or processor that for example transmits and/or receives signals to and/from valve controllers and sensors, mass flow controllers, and/or heater controllers.

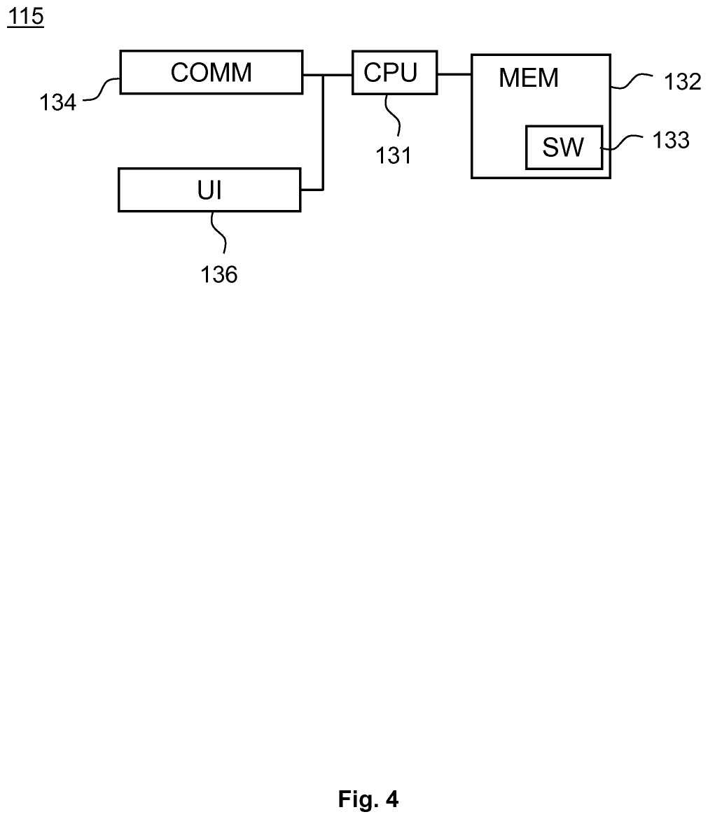

FIG. 4 shows a block diagram of the control system 115 in accordance with certain example embodiments. The control system 115 comprises at least one processor (CPU) 131 to control the operation of the apparatus 100 (FIG. 1, FIG. 2) and at least one memory (MEM) 132 comprising a computer program or software (SW) 133. The software 133 includes instructions or a program code to be executed by the at least one processor 131 to control the apparatus 100. The software 133 may typically comprise an operating system and different applications.

The at least one memory 131 may form part of the apparatus 100 or it may comprise an attachable module. The control system 115 further comprises at least one communication unit (COMM) 134. The communication unit 134 provides for an interface for internal communication of the apparatus 100. In certain embodiments, the control unit 115 uses the communication unit 134 to send instructions or commands to and to receive data from different parts of the apparatus 100, for example, measuring and control devices, valves, pumps, mass flow controllers and other adjustment devices, and heaters.

The control system 115 may further comprise a user interface (UI) 136 to co-operate with a user, for example, to receive input such as process parameters from the user. In certain embodiments, the user interface 136 is connected to the at least one processor 131.

As to the operation of the apparatus 100, the control system 115 controls e.g. process timings, flow rates, and the level of vacuum within the apparatus 100. In accordance with certain embodiments, the apparatus 100 is configured, by means of being programmed, for example, to perform a substrate processing sequence or cycle, such as an atomic layer deposition or atomic layer etching sequence or cycle.

In one embodiment the precursor container apparatus contains two parallel buffer chambers (not shown) and their control valves to enable continuous gas suction from volume A to one buffer, while other connection to the other buffer is closed for pulsing.

In one embodiment the pressure container apparatus contains pressure sensors for volume A, buffer volume E, reactor 111, incoming carrier gas 109 and incoming carrier gas via the inlet 117 and one or two directional mass flow meters in between any part (valves, volumes).

In one embodiment the pressure container apparatus contains flow restrictors, needle valves or capillaries for example to limit the flow and enable different pressures, for buffer volume E for example (not shown).

In one embodiment the chemicals, for example the precursor material and carrier gas are provided to the reaction chamber 111 from both the buffer volume E and directly from the second volume A. In other embodiments, as shown in FIG. 2, the line 116 is omitted. Accordingly, in those embodiments, the chemicals flow into the reaction chamber (reactor) only via the buffer volume E.

In one embodiment the first volume C, the second volume A, the buffer volume E, the precursor material, the valves and/or lines are heated by heating means and/or cooled by cooling means (not shown in the FIG. 1) independently or separately. In one embodiment the buffer volume E is heated more than the precursor material. In one embodiment the heating means and/or the cooling means are arranged into the first volume C, the second volume A and/or the buffer volume E. In one embodiment the heating means and/or cooling means are arranged to walls of the precursor container apparatus. In one embodiment the heating means and/or cooling means are arranged outside of the precursor container apparatus. In one embodiment the heating is by conduction and/or radiation.

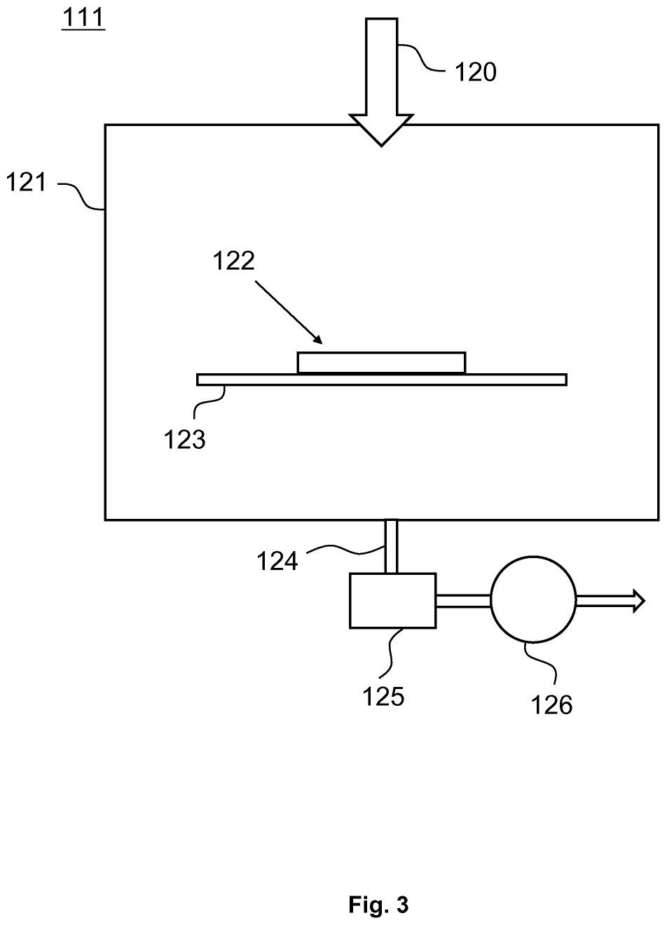

FIG. 3 shows a substrate processing apparatus (or deposition reactor) 111 in accordance with certain embodiments. The apparatus 111 comprises a reaction chamber 121, and at least one material (precursor material and/or carrier gas) inlet 120 to the reaction chamber 121. Herein the inlet(s) 120 is/are understood to comprise one or more of the inlets shown in FIG. 1, e.g., the line 116 and a line arriving from the valve 112. The apparatus 111 further comprises a fore line 124 to a pump 126, such as vacuum pump (for exhaust of gases). In one embodiment a trap 125 is positioned in the foreline 124 between the reaction chamber 121 and the pump 126. In the trap by-products of the deposition reaction are trapped and removed from the effluent gas flow before they reach the pump 126.

In the embodiment shown in FIG. 3, the inlet 120 for the precursor material and/or carrier gas is positioned in a top section of the reaction chamber 121 and the fore-line 124 in a bottom section, the general flow direction within the reaction chamber 121 thus being vertical (downwards).

A substrate support 123 supports at least one substrate 122 loaded into the reaction chamber 121 for example from a side. In one embodiment the substrate 122 is processed by ALD to produce a coating with a pre-determined number of layers of pre-determined material(s).

Without limiting the scope and interpretation of the patent claims, certain technical effects of one or more of the example embodiments disclosed herein are listed in the following. A technical effect is that a constant quantity of precursor material per pulse can be provided to the reaction chamber. A further technical effect is that the construction of the precursor container apparatus is simple. There are no moving parts in the first volume or in the second volume and level of the precursor material can be measured with external pressure sensors. Additionally, when uniform flow of precursor material is needed, the utilization of the bypassing route enables pulsing without change of the pressure in the reaction chamber.

The foregoing description has provided by way of non-limiting examples of particular implementations and embodiments of the invention a full and informative description of the best mode presently contemplated by the inventor(s) for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A precursor container apparatus, comprising:
a first volume to house precursor material;
a second volume separated from the first volume by a partition wall preventing gas exchange between the first and second volumes, the precursor container apparatus further comprising:
a route for the precursor material from the first volume to the second volume; and
an arrangement configured to raise a surface level of the precursor material via the route into the second volume and to maintain the surface level of the precursor material at a pre-determined level within the second volume.

2. The precursor container apparatus of claim 1, wherein an inlet is arranged to the first volume for providing carrier gas to the first volume.

3. The precursor container apparatus of claim 1, wherein an inlet is arranged to the first volume for providing carrier gas to the first volume for raising the precursor material level via the route to the second volume following an increase in pressure in the first volume.

4. The precursor container apparatus according to claim 1, wherein the arrangement configured to raise a surface level controls the pressure in the second volume such that the pressure is lower than pressure in the first volume thereby raising the precursor material to the second volume via the route.

5. The precursor container apparatus according to claim 1, wherein an inlet is arranged to the first volume for providing carrier gas to the first volume above the precursor material surface level.

6. The precursor container apparatus according to claim 1, wherein a valve is arranged to facilitate the route from the first volume to the second volume.

7. The precursor container apparatus according to claim 1, wherein an outlet is arranged to the second volume for discharging precursor material from the second volume.

8. The precursor container apparatus according to claim 1, wherein an outlet comprising a valve is arranged to the second volume.

9. The precursor container apparatus according to any proceeding claim 1, wherein an inlet is arranged to the second volume for providing carrier gas to the second volume.

10. The precursor container apparatus according to claim 1, wherein the precursor container apparatus further comprises a buffer chamber.

11. The precursor container apparatus according to claim 10, wherein the precursor container apparatus is configured to guide precursor material from the second volume to the buffer chamber.

12. The precursor container apparatus according to claim 1, wherein the precursor container apparatus is configured to guide precursor material from the second volume to the reaction chamber by bypassing a buffer chamber.

13. A method for handling precursor material in a precursor container apparatus comprising a first volume and a second volume separated by a partition wall, wherein the partition wall prevents gas exchange between the first and second volumes, the method comprising:
raising a surface level of the precursor material in the second volume via a route arranged from the first volume to the second volume; and
maintaining the surface level of the precursor material at a pre-determined level within the second volume.

14. The method of claim 13, wherein the method comprises providing carrier gas to the first volume via an inlet.

15. The method of claim 13, wherein the method comprises providing carrier gas to the first volume via an inlet for raising the precursor material level via the route to the second volume following an increase in pressure in the first volume.

16. The method according to any of claim 13, wherein the method comprises controlling the pressure in the second volume so that the pressure in the second volume is lower than the pressure in the first volume thereby raising the precursor material to the second volume via the route.

17. The method according to claim 13, wherein the method comprises providing carrier gas to the first volume via an inlet positioned above a precursor material surface level within the first volume.

18. The method according to claim 13, wherein the method comprises providing the route with a valve.

19. The method according to claim 13, wherein the method comprises discharging precursor material from the second volume via an outlet towards a reaction chamber.

20. The method according to claim 13, wherein the method comprises guiding precursor material from the second volume to a buffer chamber upstream of a reaction chamber.
